(19) United States
(12) Patent Application Publication
(10) Pub. No.: US 2012/0146653 A1
(43) Pub. Date: Jun. 14, 2012

(54) Trailer Light Testing Apparatus

(76) Inventor: Mark Rybolt, Bedford, IA (US)

(21) Appl. No.: 12/962,735

(22) Filed: Dec. 8, 2010

(51) Int. Cl. G01R 31/00

(52) U.S. Cl. 324/504

(57) ABSTRACT

A trailer light tester for supplying DC current to at least one circuit in a trailer where a seven pin female connector is rigidly and securely attached to a side or rear panel of the trailer light tester wherein, when the seven pin female connector which is rigidly and securely attached to the light tester is connected to the seven pin male connector which is rigidly and securely attached to the front end of the body of a truck trailer, the light tester is rigidly and securely attached to and is fully supported by the seven pin connector attached to the body of the truck trailer and projects out from the front end of the truck trailer body without requiring any additional support.

### BACKGROUND OF THE INVENTION

1. Field of the Invention

The present invention relates generally to a portable apparatus for testing electrical circuits and, more specifically, relates to apparatus for testing the continuity of circuits and operation of incandescent and LED bulbs and turn signals on trailers used for long distance hauling in the tractor trailer industry.

2. Description of Related Art

Large cross country trailers which are pulled by tractors capable of carrying 60,000 pounds or more of merchandise have a plurality of separate electrical lighting circuits which go from the front to the rear of the trailer. For example, the various circuits include marker lights which are located around the sides of the trailer, stop lights located at the rear of the trailer, left and right turn signal lights which are located at the rear of the trailer and, in some instances, on the sides of the trailer. It is necessary that each of these circuits and the light bulbs, whether they are incandescent light bulbs or LED light bulbs, are always operational to satisfy the various state and local safety requirements and the safety of the general public.

Therefore, before a trailer is connected to a tractor for a trip to a distant destination, the various lighting circuits, including the bulbs, are tested to make sure that they are in proper working condition. However, trailers normally do not carry their own batteries and may rely on a tractor to which it is connected to supply the power needed to operate the various circuit and light bulbs. In practice, the circuit and bulb testing procedure is performed at a trucking yard or terminal either while the trailer is connected to a tractor or a tractor is backed up and connected to the trailer just to test the various circuits by using the battery in the tractor as a source of power and the switches and brakes of the tractor to operate the various circuits.

Testing apparatus which provides self-contained switching circuits and power sources which can be connected to a trailer to test the various circuits and bulbs on a trailer is known in the prior art. More specifically, by way of example, U.S. Pat. No. 6,674,288 to Gumbel, et al. discloses a vehicle which provides the automatic activation and deactivation of the lights in a predetermined sequence upon user request to assist the user in making a sight inspection of the operation of the lights without further human help.

U.S. Pat. No. 6,265,878 to Traub discloses testing the circuits on a trailer without a tractor being connected thereto. A digital signal which is different for each device to be tested is encoded and wirelessly transmitted. Upon receipt of the signal, a power source is connected to the respective device to be tested. In order to reliably apply the signal in a multiplexed system in the trailer, the signal is mixed with a pseudorandom digital sequence to provide a direct sequence spread spectrum for the signal.

U.S. Pat. No. 6,172,508 to Nutt discloses a housing having a front control panel, a pair of battery terminals connected to the housing for connecting it to a battery and a cable connected to the housing having a connector which can be connected to an electrical receptacle of a trailer. A plurality of switches are connected to the battery and the connector for testing various electrical circuits in the trailer.

U.S. Pat. No. 6,081,189 to Warner discloses a battery and a flasher component electrically connected to a positive terminal of the battery. A switch is electrically connected to the flasher component and an indicator light is associated with a respective trailer light. The switch is selectively opened to de-energize the positive conductor and closed to energize the positive conductor. Attaching the harness to the lighting circuit connector component and closing the switch causes the indicator light to flash intermittently when the trailer light, positive wire and ground wire are operative and glow continuously when at least one of the trailer light, positive wire and ground wire is inoperative.

U.S. Pat. No. 5,602,482 to Gutierrez discloses a portable device for checking electrical signaling systems of trailers. An electrical circuit includes switches for energizing individual signaling circuits of the trailer individually, and indicating lamps for annunciating circuit operability. The device, which is contained on a wheeled cart, has its own power supply and circuit overcurrent protective devices, and is thus independent of a tractor which normally generates the signals.

U.S. Pat. No. 5,416,421 to Doland, Sr., et al. discloses a lamp testing apparatus having a predetermined number of battery-powered testing circuits and a connector assembly for receiving respective ends of the predetermined number of testing circuits. Lamp circuits in the trailer are placed in series with corresponding testing circuits in the testing circuitry assembly, whereby lamps in the trailer are capable of being tested by the testing circuits in the testing circuit assembly.

U.S. Pat. No. 4,884,032 to LaPensee discloses a portable testing mechanism for tractor-trailer lighting systems which permits a test of the trailer lighting system without the physical presence of the tractor, or to permit test of a tractor light control system without the physical presence of the trailer.

U.S. Pat. No. 4,866,390 to Butchko discloses an arrangement for scanning the plurality of lights in a predetermined scanning sequence. This scanning allows a single operator to check the different operating functions of the lights in a single trip around the vehicle. Thus, the scanning sequence can progress from the left turn signal to the brake lights to the right turn signal (and then repeat the cycle again) so that an operator in the back of the vehicle can watch the lights progress through this sequence.

U.S. Pat. No. 4,547,722 to Sarlo discloses a testing unit for testing the lighting of truck tractors and trailers wherein the tester can be alternately connected to the truck or the tractor and, when connected to the tractor, a battery in the tester provides power to energize the various circuits in the trailer. When the tester is connected to the trailer, various accessories on the tractor are turned on and the indicator lights on the tester will light and correspond to the accessories turned on in the tractor.

U.S. Pat. No. 3,737,767 to Slutsky discloses a portable apparatus which is operable from a battery, and includes a chassis having a plurality of switches for actuating the circuits being tested.

### SUMMARY OF THE INVENTION

In an exemplary embodiment of the present invention, there is disclosed a trailer light tester for supplying DC current to at least one circuit in a trailer where a seven pin female connector is rigidly and securely attached to a side or rear panel of the trailer light tester wherein, when the seven pin female connector which is rigidly and securely attached to the light tester is connected to the seven pin male connector which is rigidly and securely attached to the front end of the body of a truck trailer, the light tester is rigidly and securely attached to and is fully supported by the seven pin connector attached to the body of the truck trailer and projects out from the front end of the truck trailer body without requiring any additional support.

The more important features of the invention have thus been outlined in order that the more detailed description that follows may be better understood and in order that the present contribution to the art may better be appreciated. Additional features of the invention will be described hereinafter and will form the subject matter of the claims that follow.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

The foregoing has outlined, rather broadly, the preferred feature of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention and that such other structures do not depart from the spirit and scope of the invention in its broadest form.

### BRIEF DESCRIPTION OF THE DRAWINGS

Other aspects, features, and advantages of the present invention will become more fully apparent from the following detailed description, the appended claim, and the accompanying drawings in which similar elements are given similar reference numerals.

FIG. 1 is perspective view of a truck trailer light tester here disclosed which is rigidly and securely attached to a seven pin connector. When the seven pin connector on the light tester is connected to a seven pin connector that is rigidly and securely attached to the body of a truck trailer, the light tester is rigidly attached to and is supported by the body of the truck trailer and projects out from the front end of the truck trailer without any additional support;

FIG. 2 is a perspective view of the front panel of the truck trailer light tester showing a partial view of the seven pin connector extending out of the right hand end of the light tester; and

FIG. 3 is a schematic wiring diagram of the truck trailer light tester in accordance with the principles of the invention.

### DESCRIPTION OF THE PREFERRED EMBODIMENT

Annual or periodic testing of the various lighting circuits on a trailer to insure that they are operating properly is mandatory in many states and localities. Normally the testing of the lighting circuits is done by a truck mechanic while performing regular periodic maintenance on the tractor and trailer such as inspecting the brakes, tires, oil level, etc. Typically, while in the cab of the tractor, the mechanic will turn on the turn signals, marker lights, step on the break to check the brake lights, etc. and, after each operation, walk around the trailer to see if all the lights are working. Clearly, a time consuming process which can be done much faster if a second mechanic is available to help with the testing procedure.

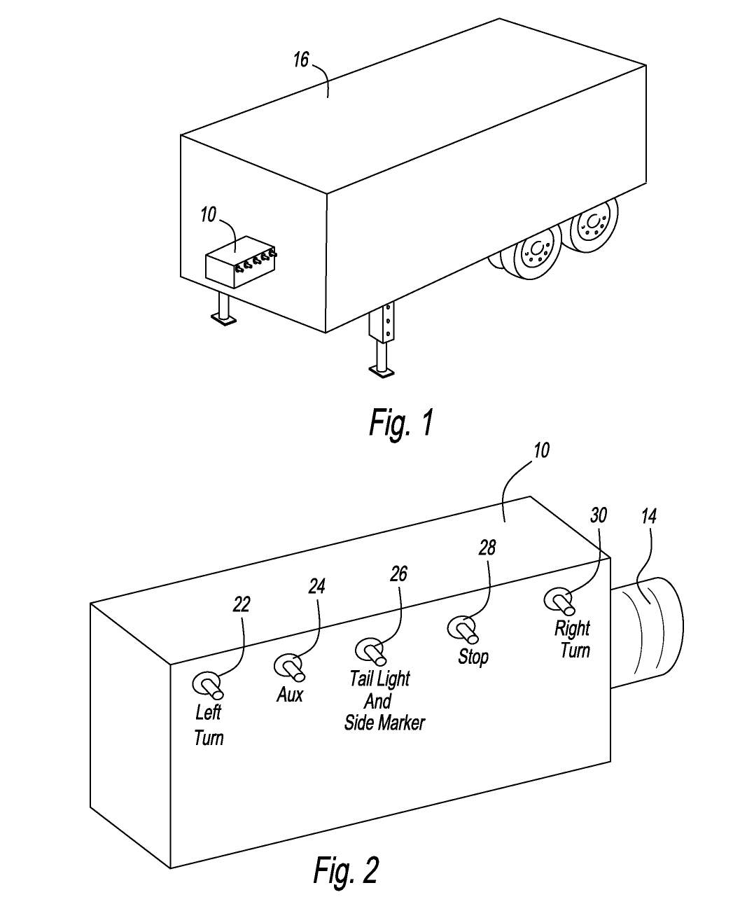

Referring to FIG. 1, there is disclosed a perspective view of a truck trailer light tester rigidly and securely attached to a seven pin female connector. When the seven pin female connector on the light tester is connected to the seven pin male connector that is rigidly attached to the front of the body of a truck trailer, the light tester is rigidly attached to and is supported by the body of the truck trailer. The light tester projects out from the front end of the truck trailer body without requiring any additional support.

The detailed description of the preferred embodiment of the invention relates to the testing of lighting circuits and bulbs on trailers which are hauled to distant locations over the interstate highway system by tractors. It is understood, however, that this invention is not limited to testing lighting circuits and bulbs on highway trailers, but may be used, for example, to test the lighting circuits of fleet rental cars, company cars, buses, etc. by simply adding an external socket which is attached to the body of the rental car, company car or bus which is connected to the lighting circuits of the vehicle that is to be tested.

Looking at FIG. 1, a trailer light testing apparatus 10 which contains its own source of twelve volt DC power or may be connected to a source of power such as a twelve volt rechargeable battery, is electrically connected through a seven prong female connector 14 (See FIG. 2) securely and rigidly attached to the light tester 10 to the lighting circuits on a trailer 16 through a seven prong male connector securely and rigidly connected to the body of a trailer.

While the number of prongs that are present in the connector is optional, the connector used with this invention has seven prongs because that is the standard connector that is currently being used on all trailers for providing power between the tractor and each of the lighting circuits on the trailer.

Referring to FIG. 2, there is shown a perspective view of the front panel of the trailer light tester apparatus where a seven pin female connector 14 is rigidly and securely attached to a side panel of the trailer light tester apparatus 10. Power is supplied to the trailer light tester apparatus from a battery which is located within the trailer light tester or may be external to and electrically connected to the trailer light tester 10 which is then selectively fed to the various lighting circuits in the trailer 16 through the female and male sections of the seven prong connector which are securely and rigidly connected to the trailer light tester and the body of the trailer.

The front panel 20 of the trailer light tester has five single pole single throw switches 22, 24, 26, 28, and 30 the functions of which are more fully identified as follows. Switch 22, left turn indicator lights; switch 24, auxiliary lights; switch 26, tail lights and marker lights; switch 28, stoplights; and switch 30, right turn lights. Following standard procedures, the switches are positioned on the front panel to be flipped either up or down where a switch is in its conducting state when it is in its up position and is in its open or non-conduction state when in its down position. If desired, light emitting diodes can be located on the front panel next to each switch to visually indicate to a user if the switch is in its conducting or non-conducting state.

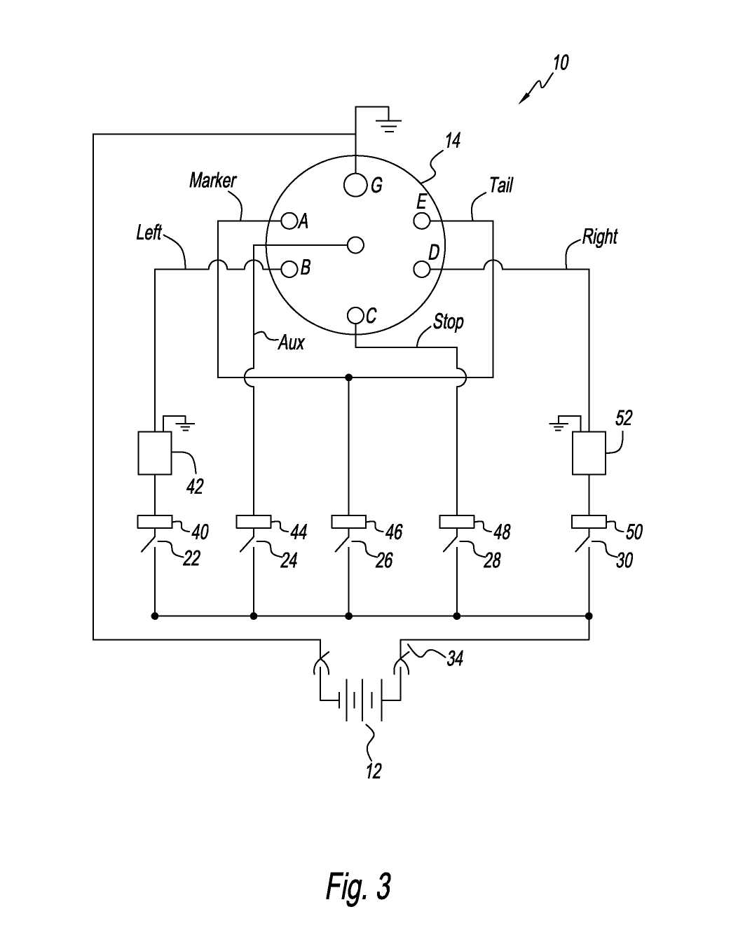

Referring to FIG. 3, there is shown a schematic wiring diagram of the truck trailer light tester apparatus in accordance with the principles of the invention. The tester 10 contains it own twelve volt rechargeable battery supply 12 which is adapted to be connected to a power supply cable 34 located within the tester which has a positive clip for attachment to the positive terminal of the twelve volt battery 12 and a ground or negative clip for attachment to the negative terminal of the battery 12. Power from the battery is controllably and selectively directed through the trailer light testing control panel 10 to a seven prong female connector 14 which is connected to ground and is rigidly and securely attached to the enclosure which is used to house the electrical circuit tester 10.

For purposes of convenience only and not intended to identify an actual pin of the connector that is connected to a specific circuit, the pins are identified with letters where, for the purposes of explanation only, pin A is the pin connector for the marker lights; pin B is the pin connector for the left turn circuit indicator lights; pin C is the pin connector for the stop lights; pin D is the pin connector for the right turn circuit indicator lights; pin E is the pin connector for the tail lights, pin F is the pin connector for the auxiliary systems circuit, and pin H is the pin connector that is connected to a ground and to the negative terminal of the twelve volt battery.

Referring now to the circuit of the trailer light testing apparatus 10, the positive battery terminal is connected to a fixed contact of a single throw single pole switch 22 for the left turn indicator light circuit, to a fixed contact of a single pole single throw switch 24 for the auxiliary light circuit, to a fixed contact of a single pole single throw switch 26 for the marker and tail light circuits, to a fixed contact of a single pole single throw switch 28 for the stop light circuit, and to a fixed contact of a single pole single throw switch 30 for the right turn indicator light circuit.

Movable contact of switch 30 is connected through fusible link 40 to the X terminal of twelve volt LED flasher 42. The L terminal of flasher 42 is connected to pin B of the seven pin connector which is the left turn indicator light circuit. Movable contact of switch 24 is connected through fusible link 44 to pin F of the seven pin connector which is the auxiliary circuit, of the trailer. The auxiliary circuit may be a circuit for different applications, oversize flashing lights, valves to dump air from moveable axles, valves to pull pins from extendable trailers, etc. Movable contact of switch 26 is connected through fusible link 46 to pins A and E of the seven pin connector which are the marker and tail light circuits of the trailer. Movable contact of switch 28 is connected through fusible link 48 to pin C of the seven pin connector which is the stop light circuit of the trailer. Movable contact of switch 30 is connected through fusible link 50 to the X terminal of a twelve volt LED flasher 52. The L terminal of flasher 52 is connected to pin D of the seven pin connector which is the right turn indicator light circuit of the trailer.

In an embodiment of the invention, the LED flashers 42, 52 may be connected in parallel with a current limiting circuit having a single throw single pole toggle switch to allow the LED flashers to be used with turn indicators which have either LED bulbs or incandescent bulbs. The current limiting circuit is connected across the LED flasher to limit the current only through the LED flasher but not to the bulbs when the bulbs in the turn indicator are incandescent by by-passing the excess current around the LED flasher. When the bulbs of the turn indicator are LED bulbs, the current limiting circuit allows the full current to pass through the LED flasher. Thus, when the turn indicators have incandescent bulbs, the current limiting circuit will only limit the current through the LED flasher but not the amount of current to the bulbs. When the turn indicators have LED bulbs, the current limiting circuit will not limit the current through the LED flasher.

While there have been shown and described and pointed out the fundamental novel features of the invention as applied to the preferred embodiments, it will be understood that the foregoing is considered as illustrative only of the principles of the invention and not intended to be exhaustive or to limit the invention to the precise forms disclosed. Obvious modifications or variations are possible in light of the above teachings. The embodiments discussed were chosen and described to provide the best illustration of the principles of the invention and its practical application to enable one of ordinary skill in the art to utilize the invention in various embodiments and with various modifications as are suited to the particular use contemplated All such modifications and variations are within the scope of the invention as determined by the appended claims when interpreted in accordance with the breadth to which they are entitled.

What is claimed is:

1. A trailer light tester for supplying DC current to at least one circuit in a trailer comprising:
a seven pin female connector rigidly and securely attached to a side or rear panel of the trailer light tester; and
a seven pin male connector rigidly and securely attached to the front end of the body of the trailer;
wherein when the seven pin female connector which is rigidly and securely attached to the light tester is connected to the seven pin male connector rigidly and securely attached to the body of a truck trailer, the light tester is rigidly and securely attached to and is fully supported by the body of the truck trailer and projects out from the front end of the truck trailer body without requiring any additional support.

2. The trailer light tester of claim 1 further comprising:
a rechargeable battery located within the light tester for supplying DC current through a first switch to a first turn indicator circuit in the trailer having at least one bulb; and
a flasher coupled in series to the first switch.

3. The trailer light tester of claim 2 wherein the flasher is an LED flasher.

4. The trailer light tester of claim 3 wherein the bulbs in the flasher are LED bulbs.

5. The trailer light tester of claim 4 further comprising a second switch for feeding current through a second LED flasher to a second turn indicator circuit in the trailer having at least one bulb.

6. The trailer light tester of claim 5 wherein the at least one bulb in the second turn indicator circuit is an LED bulb.

7. The trailer light tester of claim 6 wherein the first and second switches are single throw single pole switches.

8. The trailer light tester of claim 7 wherein a fusible link is coupled in series with the first switch and the second switch.

9. The trailer light tester of claim 8 further comprising a third switch for feeding current from the rechargeable battery to an auxiliary circuit wherein the auxiliary circuit is a circuit for oversize flashing lights, valves to dump air from moveable axles or valves to pull pins from extendable trailers.

10. The trailer light tester of claim 9 wherein a fusible link is coupled in series with the third switch.

11. The trailer light tester of claim 10 wherein the third switch is a single throw single pole switch.

12. The trailer light tester of claim 11 further comprising a fourth switch for feeding current from the rechargeable battery to a tail light and side marker circuit on the trailer.

13. The trailer light tester of claim 12 wherein a fusible link is coupled in series with the fourth switch.

14. The trailer light tester of claim 13 wherein the fourth switch is a single throw single pole switch.

15. The trailer light tester of claim 14 further comprising a fifth switch for feeding current from the rechargeable battery to a brake circuit on the trailer.

16. The trailer light tester of claim 15 wherein a fusible link is coupled in series with the fifth switch.

17. The trailer light tester of claim 16 wherein the fifth switch is a single throw single pole switch.
